(19) United States
(12) Patent Application Publication
(10) Pub. No.: US 2013/0076425 A1
(43) Pub. Date: Mar. 28, 2013

(54) INTEGRATED CIRCUIT DEVICE TIMING CALIBRATION

(71) Applicants: Kyung Suk Oh, Cupertino, CA (US); Yohan U. Frans, Sunnyvale, CA (US); Akash Bansal, Sunnyvale, CA (US); Brian S. Leibowitz, San Francisco, CA (US)

(72) Inventors: Kyung Suk Oh, Cupertino, CA (US); Yohan U. Frans, Sunnyvale, CA (US); Akash Bansal, Sunnyvale, CA (US); Brian S. Leibowitz, San Francisco, CA (US)

(21) Appl. No.: 13/702,261

(22) PCT Filed: Mar. 21, 2011
(86) PCT No.: PCT/US11/29144

§ 371 Date: Dec. 5, 2012

Related U.S. Application Data
(60) Provisional application No. 61/352,621, filed on Jun. 8, 2010.

(51) Int. Cl. H03K 5/135

(52) U.S. Cl. CPC H03K 5/135
USPC 327/263

(57) ABSTRACT

Techniques for performing timing calibration for an integrated circuit (IC) device are described. During operation, a first integrated circuit device transmits a first calibration pattern having differently delayed rising edge transitions with respect to a timing reference. The first integrated circuit device additionally transmits a second calibration pattern having differently delayed falling edge transitions with respect to the timing reference. Next, the first integrated circuit generates a timing offset for transmitting data from the first integrated circuit device. This timing offset is derived from information received from a second integrated circuit device sampling the first calibration pattern and the second calibration pattern.

### TECHNICAL FIELD

The present embodiments generally relate to techniques for communicating data between a transmitter and a receiver. More specifically, the present embodiments relate to a method and system for improving the timing accuracy of integrated circuit device data sampling.

### BRIEF DESCRIPTION OF THE FIGURES

FIG. 1A presents a block diagram illustrating a system which transmits a data signal and a clock signal over an interface 101.

FIG. 1B presents an exemplary timing diagram illustrating the phase relationship between the received data signal and sampling clock.

FIG. 2 illustrates an “eye-opening” technique and a “fuzz-median” technique which are performed on a timing calibration signal.

FIG. 3 illustrates a fuzz-median technique which leads to bimodal distribution errors when it is applied to a calibration signal.

FIG. 4A illustrates a technique for performing fuzz-median timing calibration on a calibration signal.

FIG. 4B illustrates modified techniques which improve on the techniques described in FIG. 4A.

FIG. 5 illustrates a technique for performing a fuzz-median timing calibration on a calibration signal which has a single data pattern.

FIG. 6 illustrates a technique for determining a worst-case timing center based on fuzz medians computed by two data samplers having different reference voltages.

FIG. 7 presents a block diagram illustrating an embodiment of a memory system, which includes at least one memory controller and one or more memory devices.

### DETAILED DESCRIPTION

The following description is presented to enable any person skilled in the art to make and use the invention, and is provided in the context of a particular example application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

The following description presents various example methods and apparatus for timing calibration in an integrated circuit device. In particular embodiments, two separate timing calibration runs are performed. During the first calibration run, a first timing location is determined in a timing reference based on the rising edge transitions (or the falling edge transitions). During the second calibration run, a second timing location is determined in the timing reference based on the falling edge transitions (or the rising edge transitions). The first timing location and the second timing location are then used to derive a timing offset which is subsequently used for sampling data at the integrated circuit device.

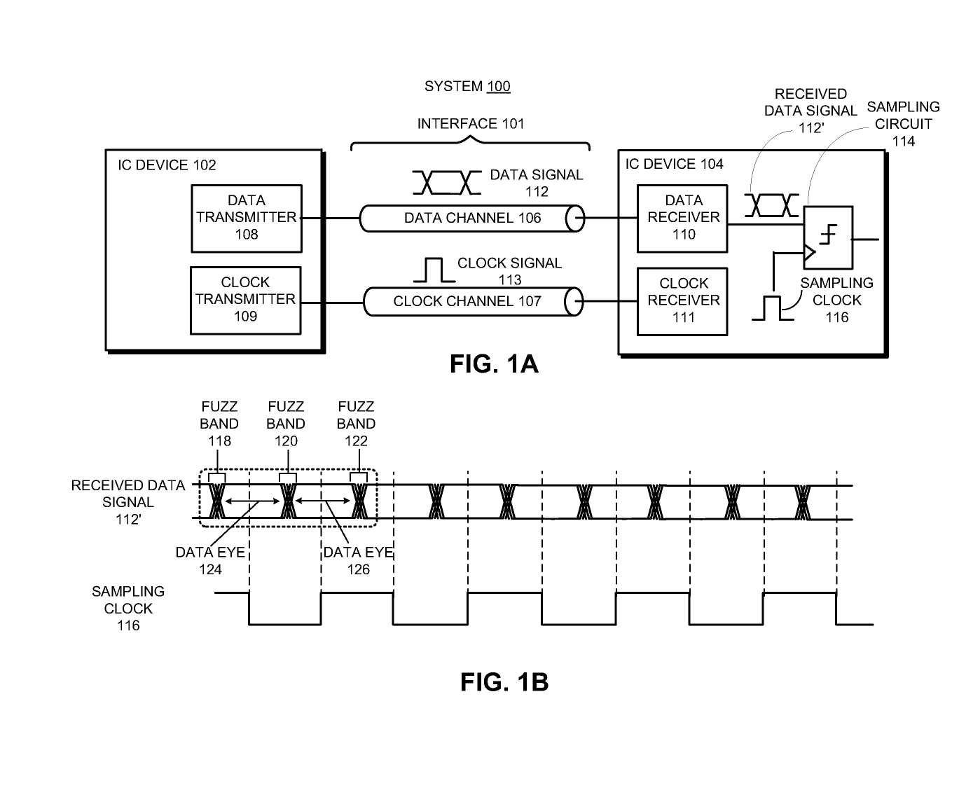

During high-speed data signaling in a digital system, data signals are transmitted from transmitting integrated circuit (IC) devices to receiving IC devices over a high-speed channel. More specifically, FIG. 1A presents a block diagram illustrating a system 100 (e.g., for chip to chip communication) which transmits a data signal and a clock signal over an interface 101. System 100 includes a first IC device 102 and a second IC device 104 coupled through interface 101, which further includes a data channel 106 and a clock channel 107. IC device 102 can further include a data transmitter 108 and a clock transmitted 109 while IC device 104 can further include a data receiver 110 and a clock receiver 111. During chip-to-chip communication, IC device 102 generates a data signal 112, which is then transmitted by data transmitter 108 over data channel 106. IC device 102 can also generate a clock signal 113, which is then transmitted by clock transmitter 109 over clock channel 107. Data signal 112 is received by data receiver 110 on IC device 104 as a received data signal 112′, while clock signal 113 is received by clock receiver 111 on IC device 104. Even if the original data signal 112 is “clean” at transmitter 108, received data signal 112′ can become “noisy” due to inter-symbol-interference (ISI), jitter, and other sources of noise in the interface 101, such as lossy data channel 106.

To resolve original data signal 112 on IC device 104, noisy data signal 112′ is sampled by a sampling circuit, which in the case of FIG. 1A is a sampling circuit 114. Note that in a double data rate (DDR)-based system, sampling circuit 114 can include two data samplers to sample the received signal 112′ on alternate rising and falling edges of a sampling clock, wherein one data sampler is used on the rising edges and the other data sampler is used on the falling edges. We refer these two data samplers as “even data sampler” and “odd data sampler,” respectively. Hence, when the even data sampler is used on the rising edges, the odd data sampler is used on the falling edges. Alternatively, when the even data sampler is used on the falling edges, the odd data sampler is used on the rising edges. For a SDR-based system equipped with two data samplers, the terms “even data sampler” and “odd data sampler” can be used to refer to the two data samplers when they are used separately on alternating cycles of a timing reference such as a clock signal or a strobe.

Sampling circuit 114 receives both data signal 112′ and a sampling clock 116, wherein clock edges in sampling clock 116 determine the timing locations when samplings take place. Note that, in some embodiments, sampling clock 116 can be replaced by a strobe signal, and can come directly from a source outside of IC device 104, such as clock signal 113 from IC device 102 or another external clock source, or can come from a clock generation circuit on IC device 104 such as a PLL or DLL. Also note that link 106 can include both a unidirectional and a bidirectional link. When link 106 is a bidirectional link, data signals can also be transmitted from IC device 104 to IC device 102, and in this scenario, each of the IC devices 102 and 104 can be both a transmitting device and a receiving device.

FIG. 1B presents an exemplary timing diagram illustrating the phase relationship between received data signal 112′ and sampling clock 116. Note that received data signal 112′ comprises noisy data transition regions, wherein each noisy data transition region can be significantly broader than the original data transitions in data signal 112. We refer to these noisy data transition regions as “fuzz bands,” and three of such fuzz bands 118, 120, and 122 are shown in FIG. 1B. Note that each fuzz band is comprised of invalid data which does not provide the correct data value at a given sampling phase. Moreover, between a pair of adjacent fuzz bands is a data eye, which defines a consistently valid data region for data sampling, e.g., data eye 124 between fuzz bands 118 and 120, and data eye 126 between fuzz bands 120 and 122. Hence, in order to read out valid data, clock edges in sampling clock 116 are positioned within the corresponding data eyes. Moreover, to maximize the signal readout, the clock edges need to be substantially aligned with the centers of the data eyes, which are often referred to as “timing centers.”

While FIG. 1B illustrates a DDR clocking scheme, the present techniques are not limited to DDR-based systems. Generally, embodiments of the present technique can be applied to a single-data-rate (“SDR”)-based system, a DDR-based system, a quad-data-rate (“QDR”)-based system, an octal data rate (“ODR”)-based system, or systems based on other types of clocking modes.

When system 100 is initially powered up, the clock edges are not necessarily aligned with the timing centers of the data signal. Hence, an initial timing calibration is typically performed to achieve this desired alignment between the data and the clock prior to performing normal system operation. Furthermore, during normal system operation, the initially calibrated timing relationship can change as a result of operating conditions (e.g., temperature variations). Consequently, the timing relationship may be recalibrated periodically to restore the desired alignment of clock edges to the timing centers. In system 100, these timing calibrations may be performed by control logic on IC device 102, or control logic on IC device 104, or control logic on both IC device 102 and IC device 104. Generally, we refer to the control logic which performs these timing calibrations as “timing calibration logic” in the discussion below.

When IC device 102 is a memory controller and IC device 104 is a memory device (e.g., a DRAM), it may be desirable to let the memory controller have the timing calibration logic and keep the memory device simple. More specifically, during write operations, the memory controller can send out the timing calibration patterns to the memory device by varying the transmit timing. The memory device receives the pattern and sends back a sampled result of the pattern. The memory controller can then determine the proper transmit timing offset based on the results received from the memory device. During read operations, the memory controller causes the memory device to transmit a pattern (typically with no timing variations) and the memory controller can then vary its sampling clock to determine the optimal sampling point (i.e., sampling timing offset) for its input sampler.

In some other embodiments, the timing calibration logic may be partitioned over both the memory controller and the memory device. In these embodiments during write operations, the memory device can perform binary phase detection when receiving the calibration pattern from the memory controller and send back a pass/fail signal. Alternatively, the memory controller can send out fixed calibration patterns and the memory device can vary its sampling timing (e.g., by doing a sweep) and a sampling timing offset can be set in the memory device instead of varying a transmit timing offset in the memory controller. Similarly, during read operations, the memory device can transmit a pattern with a timing variation and the memory controller can sample the received pattern with a fixed timing reference. In this case, a transmit timing offset is derived in the memory device. It may be preferable to calibrate the timing offset in the memory controller, rather than in a memory device, for example, because the memory controller is fabricated using a faster silicon process technology and there may be more memory devices than memory controllers in a typical system implementation.

For both the initial timing calibration and the periodic timing recalibration, two techniques may be used to calibrate the timing centers. These two techniques are referred to as the “eye-opening” timing calibration technique (or the “eye-opening technique”) and the “fuzz-median” timing calibration technique (or the “fuzz-median technique”), respectively. Embodiments of the present technique can be applied to both the initial timing calibration and the periodic timing recalibration for system 100.

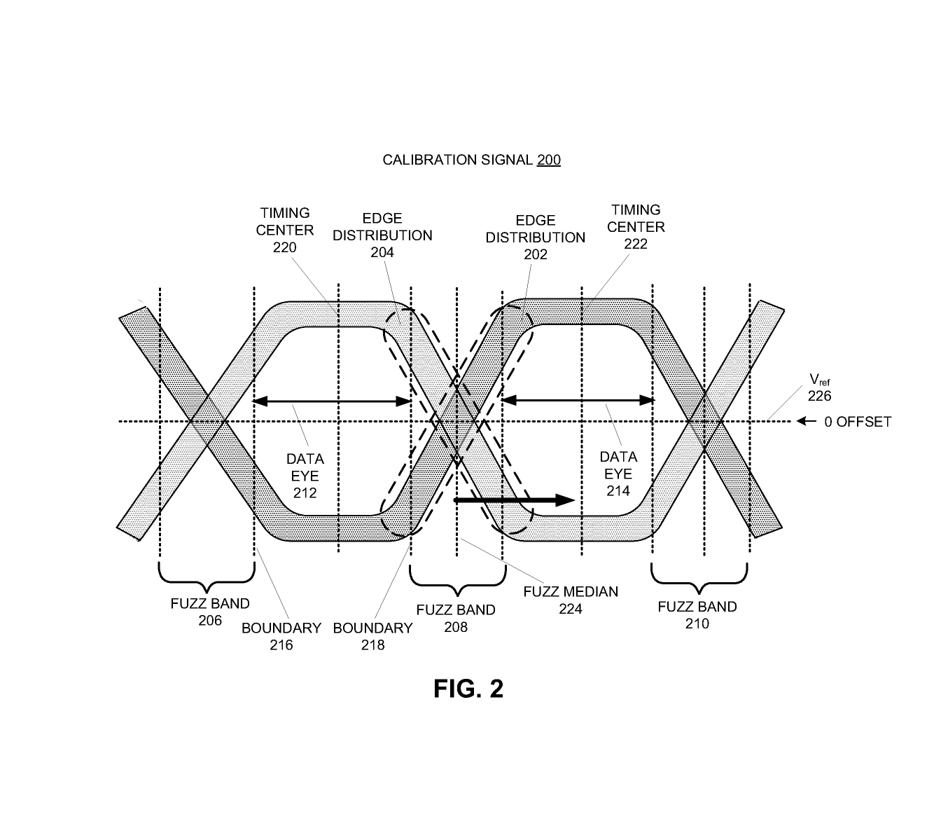

FIG. 2 illustrates an eye-opening technique and a fuzz-median technique which are performed on a timing calibration signal 200. In one embodiment, calibration signal 200 provides a close-up view of the portion of received data signal 112′ which includes fuzz bands 118-122 and data eyes 124 and 126. More specifically, calibration signal 200 includes two overlapping data patterns which are 180° out of phase from each other. Calibration signal 200 also includes a number of noisy data transitions, wherein each noisy data transition is characterized by an edge distribution represented by a shaded and sloped area in the data patterns. For example, an edge distribution 202 corresponds to a rising data transition while an edge distribution 204 corresponds to a falling data transition. A “fuzz band” in calibration signal 200 can be defined as a region which is centered around a cross-over region of a rising edge distribution and a falling edge distribution, and extends on both sides of the cross-over region to boundary locations where the bit error ratio (BER) from sampling at the boundary locations is below a predetermined BER threshold.

For example, calibration signal 200 includes three fuzz bands 206, 208, and 210 (each defined between a pair of boundaries), wherein fuzz band 208 includes both edge distributions 202 and 204. We refer to the center in the time axis (i.e., the horizontal axis) of a fuzz band as a “fuzz median” below. Note that a fuzz median can also be defined in the present techniques as a location in the fuzz band where sampling at that location has a substantially equal probability of getting an early or a late decision. One embodiment determines if a current sample at a given data transition is an early decision or a late decision as follows: if the current sample value agrees with a preceding data eye, the current sample is an early decision; if the current sample value agrees with the succeeding data eye, the current sample is a late decision. Data eyes are formed as the open areas between a pair of adjacent fuzz bands, and when DDR clocking is used, each data eye corresponds to a valid data bit in calibration signal 200. A “timing center” is the center of the data eye where a substantially optimal signal readout can be obtained.

An eye-opening technique for locating a timing center first locates the boundaries of a data eye, such as boundaries 216 and 218 of data eye 212, beyond which data eye 212 cannot be reliably sampled. The technique then determines the timing center as the averaged position of the two boundaries, such as timing center 220 of data eye 212 and timing center 222 of data eye 214. While the eye-opening technique can typically find an accurate timing center of a data eye, this technique requires many test bits to be transmitted in order to create a worst-case eye opening (by broadening the fuzz bands on each side of the data eye as much as possible, so that the located boundaries of a data eye correspond to worst-case outliers). However, using a large number of data bits may involve a relatively long calibration procedure.

A fuzz-median technique attempts to first locate the fuzz median of a fuzz band between two adjacent data eyes. In one embodiment, to find the fuzz median the timing calibration logic samples within fuzz bands (such as fuzz band 208) and collects early/late decisions over a sequence of transitions, for example using a bang-bang phase detector. While performing timing calibration, the timing calibration logic continuously adjusts the sampling location within the fuzz band until the early/late statistics produce substantially equal numbers of early and late decisions. Once the fuzz median (e.g., fuzz median 224) is located, a timing center can be obtained by simply adding a 90° phase shift to the located fuzz median. Note that the fuzz-median technique often ignores the worst-case outliers, and therefore requires fewer test bits and shorter calibration time, but can be less accurate than the eye-opening technique, and 90° phase shifts can be generated with good accuracy in many clocking systems.

Note that FIG. 2 illustrates an ideal scenario of performing a fuzz-median timing calibration, where it is assumed that the sampling operations use a sampler which receives a reference voltage V_{ref} 226 that is substantially equal to zero. Here there is also an assumption that calibration signal 200 for timing calibration has a 50/50 duty cycle (in both data patterns). Based on these assumptions, the timing calibration within a fuzz band will locate the true fuzz median.

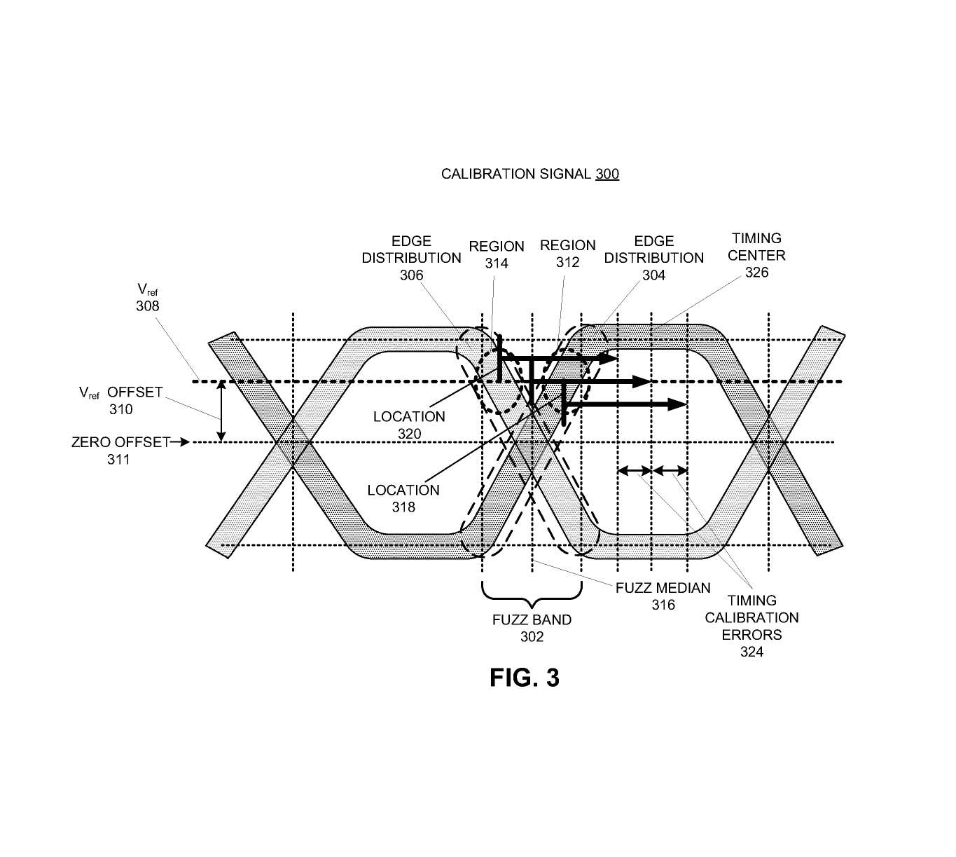

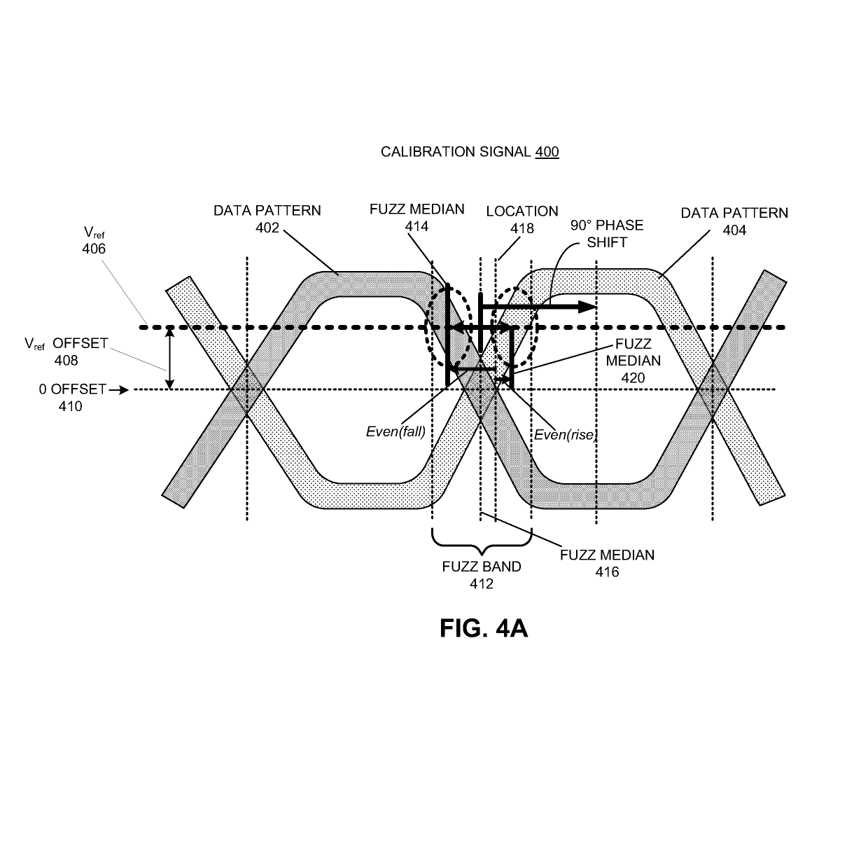

FIG. 3 illustrates a fuzz-median technique which leads to bimodal distribution errors when it is applied to a calibration signal 300. Calibration signal 300, which is constructed similar to calibration signal 200, includes a fuzz band 302, which further includes a rising edge distribution 304 and falling edge distribution 306. In the example of FIG. 3, the sampler used to search for the fuzz median of fuzz band 302 is associated with a reference voltage V_{ref} 308 which has a non-zero V_{ref} offset 310 from zero offset position 311. Because of this offset, V_{ref} 308 intercepts fuzz band 302 at locations where rising and falling edge distributions 304 and 306 separate from each other, creating bimodal distributions. Consequently, when sampling in fuzz band 302 while performing the fuzz-median technique, the clock edge for the sampler could lock to any time between these two distributions. At any such time, the sampler will consider all falling transitions as late samples (sampled after the transition), and all rising transitions as early samples (sampled before the transition), and thus any time between the two distributions satisfies the fuzz-median technique. This uncertainty in the detected fuzz-median timing leads to timing calibration errors referred to as “bimodal distribution errors.”

Note that duty-cycle distortion (DCD) can also add to bimodal distribution errors, even when the V_{ref} offset is zero. This is because, when there are DCD effects in the periodic data pattern, each period of data pattern becomes a long pulse plus a short pulse, and two such waveforms may not cross each other in the middle (in the vertical direction) of the waveforms. Typically, the V_{ref} offset contributes to a major portion of the bimodal distribution errors, while DCD effects contribute a minor portion of the bimodal distribution errors. More detail regarding correcting bimodal distribution errors as a result of both of these problems can be found below.

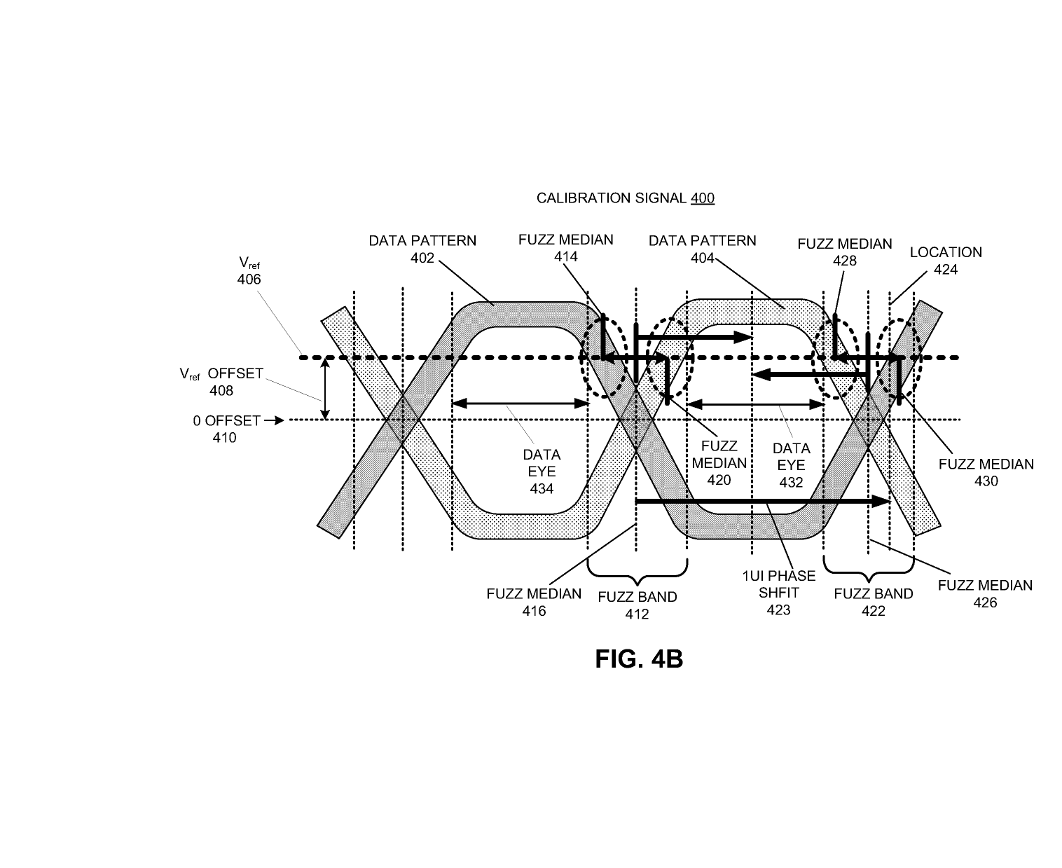

FIG. 4A illustrates a technique for performing fuzz-media timing calibration in accordance with an embodiment. Calibration signal 400, which is constructed similar to calibration signal 300, includes two data patterns 402 and 404. In FIG. 4A, difference shadings are used to distinguish these two data patterns. In the instant embodiment, data pattern 404 is a phase-inverted version of data pattern 402, and the two data patterns have a constant phase difference of 180°. In one embodiment, data patterns 402 and 404 are clock signals.

While FIG. 4A illustrates data patterns 402 and 404 overlapping each other in time, some embodiments of the presently described technique transmit the two data patterns at different times so that they are received and sampled at different times without overlapping. In these embodiments, the overlapping shown in FIG. 4A is for the purpose of illustrating the phase relationship between the two data patterns, but is not intended to suggest that the two data patterns are simultaneously transmitted.

While each of data patterns 402 and 404 is shown to have a 50/50 duty cycle and near perfect symmetry between the two halves of a data period, the DCD effects can cause distortions in these data patterns. These distortions can cause two adjacent data eyes to have different widths and the rising and falling transitions of the data pulses to have different slopes. Hence, embodiments of the present techniques can be equally applied to calibration signals which suffer from the DCD effects.

In one embodiment, only one data sampler is used to sample calibration signal 400 during a proposed timing calibration operation. In a DDR-based system which uses both an even data sampler and an odd data sampler to resolve received data signals, either the even or the odd data sampler can be used in this embodiment. The single data sampler used in this embodiment is referred to as an “even sampler” below. Note that this “even sampler” can be either the even data sampler or the odd data sampler. Because the even data sampler and the odd data sampler were defined above to be used interchangeably, the term “even sampler” is used as an identifier of one of the two samplers. In a system which only uses a single data sampler, the term “even sampler” is used as an identifier for this single data sampler.

In the example of FIG. 4A, the even sampler used to sample calibration signal 400 is associated with a reference voltage V_{ref} 406 which has a non-zero V_{ref} offset 408 from the zero offset position 410. Moreover, because of this offset, V_{ref} 406 intercepts a fuzz band (e.g., fuzz band 412) in calibration signal 400 at locations where the separation of the bimodal distributions takes place. Consequently, sampling in fuzz band 412 based on the fuzz-median technique will likely cause bimodal distribution errors.

In one embodiment, two separate timing calibration runs are performed. During the first calibration run, data pattern 402 is first received at the receiver, and the even sampler is used to determine a first timing location in data pattern 402 based on either the rising edge distributions or the falling edge distributions. More specifically, the timing calibration logic uses the fuzz-median technique described in conjunction with FIG. 2 to determine a first fuzz median. While FIG. 4A illustrates a scenario of sampling and determining the first fuzz median within the falling edge distributions of data pattern 402, other embodiments can look for the first fuzz median in the rising edge distributions of data pattern 402. Because fuzz band 412 only includes a falling edge distribution (the rising edge distribution does not exist during the first calibration run), the fuzz-median technique will exclusively determine fuzz median 414 in the falling edge distributions. Note that fuzz median 414 is not the true fuzz median 416 of fuzz band 412. Assume that a location 418 is the initial sampling location for the first calibration run. This first timing location, obtained from falling edge distributions, is referred to as Even(fall), which typically represents an offset from location 418 to fuzz median 414.

During the second calibration run (which can be performed either before or after the first calibration run), data pattern 404 is received at the receiver, and the even sampler is used to determine a second timing location in data pattern 404 based on either the rising edge distributions or the falling edge distributions. Note, however, that if the first timing calibration is performed on the falling edge distributions, the second timing calibration has to be performed on the rising edge distributions, or vice versa. More specifically, the timing calibration logic uses the fuzz-median technique described in conjunction with FIG. 2 to determine a second fuzz median. FIG. 4A illustrates a scenario of sampling and determining the second fuzz median within the rising edge distributions of data pattern 404 because the first fuzz median is determined in the falling edge distributions of data pattern 402. As shown in FIG. 4A, because fuzz band 412 only includes the rising edge distribution (the falling edge distribution does not exist during the second calibration run), the fuzz-median technique will exclusively determine fuzz median 420 in the rising edge distributions. Note that fuzz median 420 is not the true fuzz median 416 of fuzz band 412. Assume that location 418 is also the initial sampling location for the second calibration run. This second timing location obtained from rising edge distributions is referred to as Even(rise), which typically represents an offset from location 418 to fuzz median 420.

Once the two fuzz medians have been located in the bimodal distributions, the true fuzz median 416 of fuzz band 412 can be located in the middle of fuzz median 414 and fuzz median 420 because of the symmetry of fuzz band 412. In one embodiment, fuzz median 416 is obtained by averaging fuzz medians 414 and 420, which can be expressed as:

Average[Even(rise), Even(fall)].

From the hardware perspective, the output of the timing calibration Average[Even(rise), Even(fall)] represents an offset between fuzz median 416 and the uncalibrated sampling location 418. Consequently, the timing center of a data eye is obtained by adding a 90° phase shift to the established offset:

90°+Average[Even(rise), Even(fall)].

Next, the obtained timing center can be used to align a clock signal for sampling a data signal at the receiving device. In some systems the 90° phase shift may not result in the ideal sampling location and the better location would be slightly offset to this location. The proposed method works with any phase offset other than 90°.

Knowing the two timing locations Even(rise), Even(fall) also facilitates determining V_{ref} offset 408 for the even sampler, which is a combined offset from both the transmitter side (e.g., Vᵢₙ offset) and the receiver side. Once V_{ref} offset 408 is known, the timing calibration logic can attempt to compensate for the Vᵢₙ offset in order to reduce or eliminate the bimodal distribution errors. This compensation adjustment can take place on either the transmitter side (e.g., by shifting the data patterns up or down) or the receiver side (e.g., by adjusting the reference voltages for the samplers).

Note that in FIG. 4A a 90° phase shift from the determined fuzz median 416 may not represent the best timing center when there are DCD distortions in calibration signal 400. FIG. 4B illustrates modified techniques which improve on the techniques described in FIG. 4A.

More specifically, after determining the location of fuzz median 416 following the technique of FIG. 4A, the sampling location of the even sampler may be delayed by 1 unit interval (UI) (shown as phase shift 423) or 180° from fuzz median 416 to a region within an adjacent fuzz band 422, for example, to a location 424 within fuzz band 422. Note that, if the DCD effects do not exist in calibration signal 400, location 424 is essentially a fuzz median 426 of fuzz band 422. However, because of the DCD effects, location 424 is different from fuzz median 426.

In some embodiments, the 1UI delay can be achieved by delaying the sampling clock of the even sampler. For example, when the sampling clock is transmitted along with calibration signal 400 from the transmitting device to the receiving device, this delay can take place either on the transmitting device prior to transmitting the sampling clock, or on the receiving device after the sampling clock is received at the receiving device. Alternatively, this delay can be achieved by advancing calibration signal 400 by 1UI at the transmitting device relative to the sampling clock prior to transmitting calibration signal 400 and the sampling clock.

After the delay, the calibration process described in FIG. 4A is repeated on data patterns 402 and 404 to obtain fuzz medians 428 and 430 based on the falling edge distributions and the rising edge distributions, respectively, and the average of these results provides the location of fuzz median 426 of fuzz band 422. As mentioned above, the output of the calibration is the offset between fuzz median 426 and location 424. According to the above convention, the fuzz median 426 may be expressed as Average[Even(rise, 1UI), Even(fall, 1UI)], wherein “1UI” in the expression represents the 1UI phase shift from fuzz median 416. Finally, the timing center of data eye 432 between fuzz band 412 and 422 is obtained by taking the average of the determined offsets to fuzz median 416 and fuzz median 426, and then adding a 90° phase shift:

90°+Average{Average[Even(rise), Even(fall)], Average[Even(rise, 1UI), Even(fall, 1UI)]}.

Next, the obtained timing center can be used to align a clock signal for sampling a data signal at the receiving device.

When calibration signal 400 is distorted by the DCD effects, each signal period becomes a long pulse and a short pulse. As a result, adjacent data eyes 432 and 434 may have different eye opening widths caused by the DCD effects. In some embodiments, the timing calibration described in FIG. 4B is performed on the smaller eye opening of the two adjacent data eyes. These embodiments are based on an assumption that a smaller eye opening is more likely to cause sampling errors than the larger eye openings. The exemplary operation of FIG. 4B may be based on the assumption that data eye 432 is smaller than data eye 434.

Note that in DDR-based systems, the even and odd data samplers have a fixed 1UI phase difference. Hence, when two data samplers (even and odd) have substantially the same V_{ref} offset, the timing calibration logic can perform the same operation in FIG. 4B by using both even and odd data samplers. For example, the even data sampler is used to locate fuzz median 416, while the odd data sampler is used to locate fuzz median 426. However, because the even and odd data samplers typically share a common clock, the calibrations for finding both fuzz medians need to be performed separately. In one scenario, four calibration runs are taken: run #1 involves using data pattern 402 and the even data sampler to find fuzz median 414; run #2 involves using data pattern 404 and the even data sampler to find fuzz median 420; run #3 involves using data pattern 402 and the odd data sampler to find fuzz median 430; and run #4 involves using data pattern 404 and the odd data sampler to find fuzz median 428. Note that, in this two-sampler embodiment, the 1UI phase shifts in FIG. 4B are avoided.

In general, the techniques described in conjunction with FIG. 4B require more calibration time than the techniques described in conjunction with FIG. 4A. However, by taking into account the effects of DCD, techniques described in conjunction with FIG. 4B also generate more accurate timing centers than those in FIG. 4A.

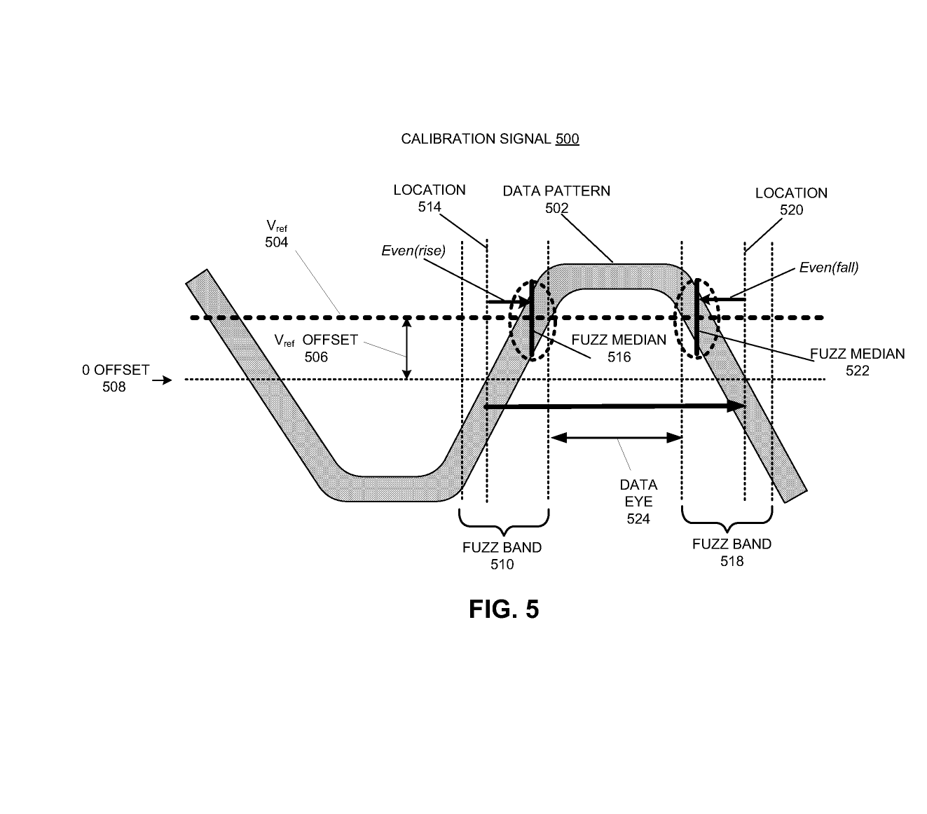

FIG. 5 illustrates a technique for performing a fuzz-median timing calibration on a calibration signal 500 which has a single data pattern.

Unlike calibration signal 400, calibration signal 500 comprises a single data pattern 502. In one embodiment, data pattern 502 is a clock signal. Note that, while data pattern 502 is shown having a 50/50 duty cycle and near perfect symmetry between the two halves of a signal period, the DCD effects can cause distortions in data pattern 502 in a similar manner as data pattern 402 in FIG. 4A and FIG. 4B. Hence, embodiments of the present techniques can be equally applied to calibration signals which are distorted by the DCD effects.

In one embodiment, only one data sampler is used to sample calibration signal 500 during a proposed timing calibration operation. In the DDR-based systems, this data sampler can be either the even data sampler or the odd data sampler. In an embodiment, it is assumed that the even data sampler is used in the example of FIG. 5 although the instant description would be equally applicable if the odd data sampler is used instead.

In the example of FIG. 5, the even data sampler used to sample calibration signal 500 is associated with a reference voltage V_{ref} 504 which has a non-zero V_{ref} offset 506 from zero offset 508. Although not explicitly shown, V_{ref} offset 506. As a result of offset V_{ref} 506, sampling in fuzz band 510 based on the fuzz-median technique will not converge to an ideal fuzz median in the center of fuzz band 510.

In one embodiment, the timing calibration logic performs two calibration runs: one for the falling edge distributions to find the first median in data pattern 502, and the other for the rising edge distributions to find the second median.

More specifically, during the first timing calibration run, the even sampler is used to determine a first timing location in data pattern 502 based on either the rising edge distributions or the falling edge distributions. More specifically, the timing calibration logic uses the fuzz-median technique described in conjunction with FIG. 2 to determine a first fuzz median. Assume a location 514 within fuzz band 510 as the initial sampling location of the even data sampler. As shown in FIG. 5, the fuzz-median technique determines a fuzz median 516 within fuzz band 510 based on the rising edge distributions. Because of offset 506, fuzz median 516 is different from the ideal fuzz median of fuzz band 510. This first timing location is referred to as Even(rise), which typically represents an offset from location 514 to fuzz median 516.

After determining the first timing location, the sampling location of the even sampler is delayed by 1UI or 180° from fuzz median 516 to a location within an adjacent fuzz band 518, for example, to a location 520. The 1UI delay can be achieved by either delaying the sampling clock or advancing calibration signal 500 as described above. After the delay, the second timing calibration run is performed using the even data sampler to determine a second timing location in data pattern 502. More specifically, the system uses the fuzz-median technique described in conjunction with FIG. 2 to determine a second fuzz median 522 within fuzz band 518 based on the falling edge distributions. Because of offset 506, fuzz median 522 is different from the ideal fuzz median of fuzz band 518. This first timing location is referred to as Even(fall), which typically represents an offset from location 520 to fuzz median 522.

Once fuzz median 516 and fuzz median 522 have been located in data pattern 502, the timing center of a data eye 524 between fuzz band 510 and fuzz band 518 can be located in the middle of the two fuzz medians. In one embodiment, the timing center of data eye 524 can be obtained by adding a 90° phase shift to the average of the two fuzz medians:

90°+Average[Even(rise), Even(fall)].

Next, the obtained timing center can be used to align a clock signal for sampling a data signal at the receiving device.

Note that in DDR-based systems, the even and odd data samplers have a fixed 1UI phase difference. Hence, when both data samplers have substantially the same V_{ref} offset 506, the timing calibration logic can perform the same operation in FIG. 5 by using both even and odd data samplers. For example, the even data sampler is used to locate fuzz median 516 while the odd data sampler is used to locate fuzz median 522. However, because the even and odd data samplers typically share a common clock, the calibrations for finding both fuzz medians are performed separately in two runs. This two-sampler variation will obtain the same timing center as the single sampler approach but avoids the 1UI phase shifts in FIG. 5.

Note that, for all the techniques described in conjunctions with FIG. 4A, FIG. 4B, and FIG. 5, when the even data sampler and the odd data sampler have different reference voltages, reference is made to using only one of the two data samplers to determine the timing center. The selected data sampler produces a timing center which will subsequently be used by both the even and odd samplers. However, this timing center which is optimized for the reference voltage of the selected data sampler may not work optimally with the reference voltage of the unselected data sampler. To mitigate this issue, some embodiments can separately calibrate both data samplers. More specifically, each of the data samplers can be separately used to determine a respective timing center (referred to as tc(even) and tc(odd)) for a data eye based on techniques described in FIG. 4A, FIG. 4B, or FIG. 5. Because of the different reference voltages, tc(even) and tc(odd) typically end up different from each other. Note that such a calibration requires twice the calibration time compared to its single sampler counterpart.

At this point, a number of options can be taken. In one embodiment, the timing calibration logic simply takes the average of the two timing centers: Average(tc(even), tc(odd)) as the final calibrated time center for both samplers. In another embodiment, the timing calibration logic picks the worst-case timing center between tc(even) and tc(odd) as the final calibrated time center for both samplers. For example, this worst-case timing center can be associated with the data sampler which determines a smaller data eye opening than the other data sampler.

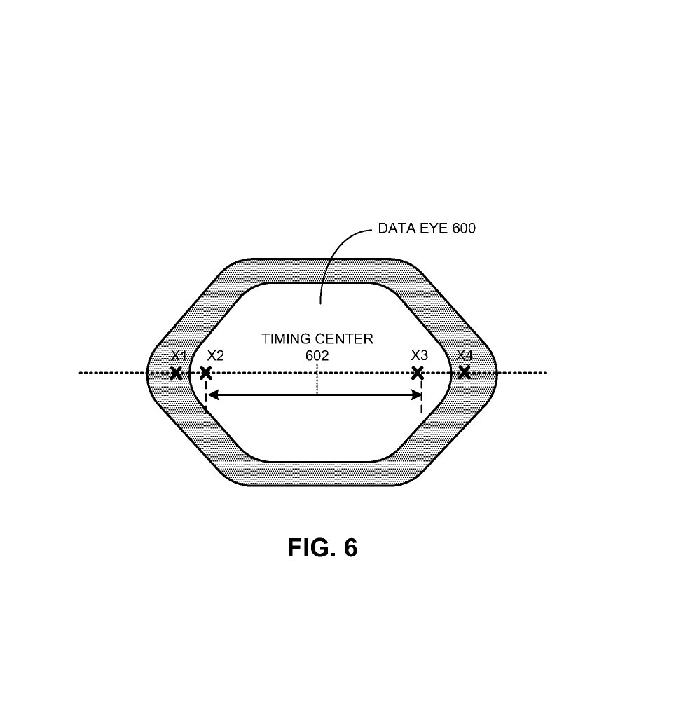

In yet another embodiment, the timing calibration logic combines the fuzz medians computed by both of the samplers, and then determines a new timing center based on the combined information. FIG. 6 illustrates a technique for determining a worst-case timing center based on fuzz medians computed by two data samplers having different reference voltages. As shown in FIG. 6, data eye 600 is associated with four fuzz medians computed by the two samplers, wherein each data sampler determines one fuzz median on each side of data eye 600. More specifically, fuzz medians X1 and X2 are located on the left side of data eye 600, while fuzz medians X3 and X4 are located on the right side of data eye 600. Without specifying which data sampler is used to determine which of the four fuzz medians, one technique simply picks the innermost two fuzz medians X2 and X3, and computes a timing center 602 for both data samplers. Note that it is possible that X2 and X3 are obtained by more than one data sampler. Consequently, this technique attempts to choose the best timing center for both samplers.

Embodiments of the present disclosure provide a number of improved fuzz-median techniques. The present techniques significantly improve the timing center calibration accuracy over the conventional fuzz-median technique. These improvements come from mitigating both the bimodal distribution errors and the DCD-induced errors without the need for separately fixing the two types of errors. Moreover, when mitigating the bimodal distribution errors, the present techniques simultaneously fix the bimodal distribution errors caused by reference voltage offsets from both the transmitter side and the receiver side. These techniques can also determine a combined (i.e., system level) reference voltage offset of both the transmitter and the receiver, which facilitates eliminating this offset by compensating for the offset from either side of the communication channel Moreover, these techniques can be applied on a data pattern which is generated using sub-rates. For instance, when the data channel is not very stable, it may be desirable to use lower data rates while using the same clock signal.

Although some embodiments of the presently described techniques involve performing phase-averaging operations, these operations are only applied to locations having very small phase differences and hence do not introduce any significant INL error. Improved fuzz-median techniques remain faster than the conventional eye-opening technique but can achieve even better BER than the conventional eye-opening technique.

The above-described techniques and apparatus can be used in different systems employing different types of memory devices and memory controllers that control the operation of these memory devices. Examples of these systems include, but are not limited to, mobile systems, desktop computers, servers, and/or graphics applications. The memory devices can include dynamic random access memory (DRAM). Moreover, the DRAM may be, e.g., graphics double data rate (GDDR, GDDR2, GDDR3, GDDR4, GDDR5, and future generations) and double data rate (DDR2, DDR3 and future memory types).

The techniques and apparatus described may be applicable to other types of memory or integrated circuit devices, for example, system on chip (“SoC”) implementations, flash and other types of non-volatile memory and static random access memory (SRAM).

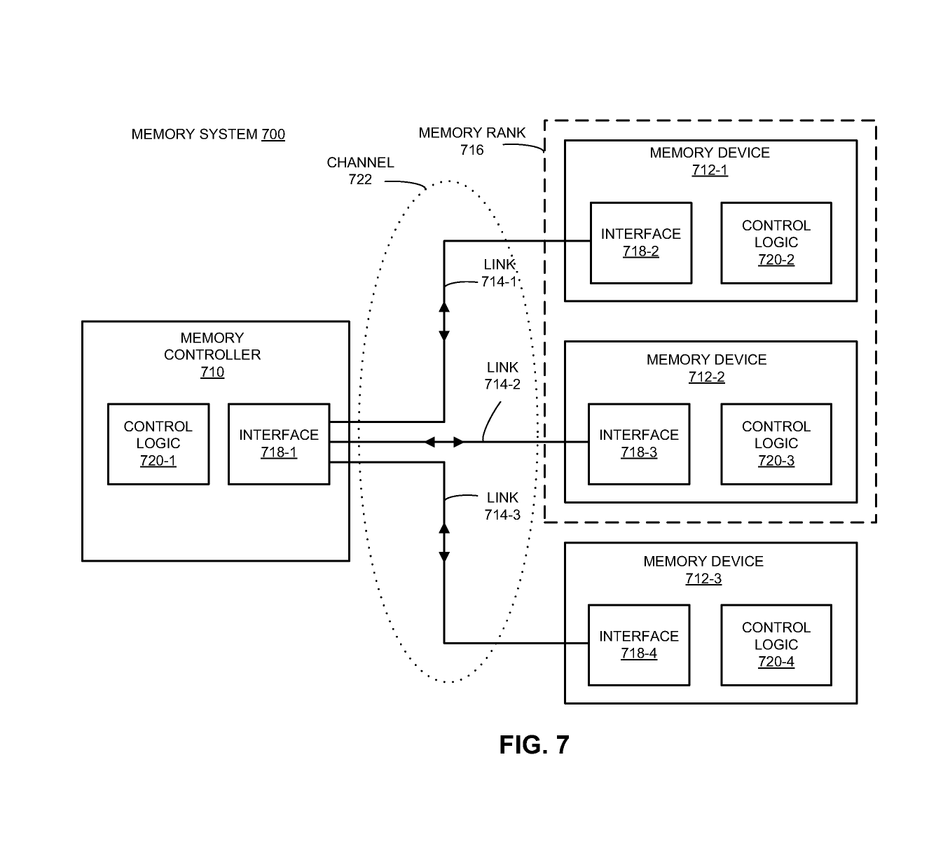

Additional embodiments of memory systems that may use one or more of the above-described apparatus and techniques are described below with reference to FIG. 7. FIG. 7 presents a block diagram illustrating an embodiment of a memory system 700, which includes at least one memory controller 710 and one or more memory devices 712. While FIG. 7 illustrates memory system 700 with one memory controller 710 and three memory devices 712, other embodiments may have additional memory controllers and fewer or more memory devices 712. Note that the one or more integrated circuits may be included in a single chip-package, e.g., in a stacked configuration.

In some embodiments, memory controller 710 is a local memory controller (such as a DRAM memory controller) and/or is a system memory controller (which may be implemented in a microprocessor, an application-specific integrated circuit (ASIC), a System-on-a-chip (SoC) or a Field-programmable gate array (FPGA)).

Memory controller 710 may include an I/O interface 718-1 and control logic 720-1. In some embodiments, one or more of memory devices 712 include control logic 720 and at least one of interfaces 718. However, in some embodiments some of the memory devices 712 may not have control logic 720. Moreover, memory controller 710 and/or one or more of memory devices 712 may include more than one of the interfaces 718, and these interfaces may share one or more control logic 720 circuits. In some embodiments two or more of the memory devices 712, such as memory devices 712-1 and 712-2, may be configured as a memory rank 716.

As discussed in conjunction with FIGS. 4A, 4B, 5 and 6, one or more of control logic 720-1, control logic 720-2, control logic 720-3, and control logic 720-4 may be used to control various timing calibrations of the present techniques to locate accurate timing centers. Memory controller 710 may also generate various timing calibration signals to be transmitted to one or more of memory devices 712.

Memory controller 710 and memory devices 712 are coupled by one or more links 714, such as multiple wires, in a channel 722. While memory system 700 is illustrated as having three links 714, other embodiments may have fewer or more links 714. Moreover, these links may provide: wired, wireless and/or optical communication. Furthermore, links 714 may be used for bi-directional and/or unidirectional communication between the memory controller 710 and one or more of the memory devices 712. For example, bi-directional communication between the memory controller 710 and a given memory device may be simultaneous (full-duplex communication). Alternatively, the memory controller 710 may transmit a command to the given memory device, and the given memory device may subsequently provide requested data to the memory controller 710, e.g., a communication direction on one or more of the links 714 may alternate (half-duplex communication). Also, one or more of the links 714 and corresponding transmit circuits and/or receive circuits may be dynamically configured, for example, by one of the control logic 720 circuits, for bidirectional and/or unidirectional communication.

Signals corresponding to data and/or commands (such as request-for-data commands) may be communicated on one or more of the links 714 using either or both edges in one or more timing signals. These timing signals may be generated based on one or more clock signals, which may be generated on-chip (for example, using a phase-locked loop and one or more reference signals provided by a frequency reference) and/or off-chip.

In some embodiments, commands are communicated from the memory controller 710 to one or more of the memory devices 712 using a separate command link, i.e., using a subset of the links 714 which communicate commands. However, in some embodiments commands are communicated using the same portion of the channel 722 (i.e., the same links 714) as data.

Devices and circuits described herein may be implemented using computer-aided design tools available in the art, and embodied by computer-readable files containing software descriptions of such circuits. These software descriptions may be: behavioral, register transfer, logic component, transistor and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A method of operation of an integrated circuit device, the method comprising:
transmitting, from a first integrated circuit device, a first calibration pattern having differently delayed rising edge transitions with respect to a timing reference;
transmitting, from the first integrated circuit device, a second calibration pattern having differently delayed falling edge transitions with respect to the timing reference; and
generating a timing offset for transmitting data from the first integrated circuit device, wherein the timing offset is derived from information received from a second integrated circuit device sampling the differently-delayed rising edge transitions of the first calibration pattern and the differently-delayed falling edge transitions of the second calibration pattern.

2. The method of claim 1, wherein generating the timing offset comprises:
determining a first timing location with respect to the timing reference based at least on the sampled differently-delayed rising edge transitions;
determining a second timing location with respect to the timing reference based at least on the sampled differently-delayed falling edge transitions;
computing a third timing location by averaging the first timing location and the second timing location; and
generating the timing offset by adding a predetermined phase shift to the third timing location.

3. The method of claim 2,
wherein determining the first timing location comprises locating a first median location within the differently delayed rising edge transitions; and
wherein determining the second timing location comprises locating a second median location within the differently delayed falling edge transitions.

4. The method of claim 2, wherein the predetermined phase shift is a substantially 90° phase shift.

5. The method of claim 1, wherein the method further comprises:
transmitting the data delayed by the timing offset from the first integrated circuit device to the second integrated circuit device; and
sampling the data at the second integrated circuit device with a clock signal, wherein clock transitions in the clock signal are aligned to be substantially in a center of a data bit in the data.

6. The method of claim 1, wherein the second calibration pattern is a phase-inverted version of the first calibration pattern.

7. The method of claim 1, wherein the first calibration pattern and the second calibration pattern are the same calibration pattern.

8. The method of claim 1, wherein the first integrated circuit device is a memory controller device and the second integrated circuit device is a memory device.

9. An integrated circuit device, comprising:
an interface to transmit first and second calibration patterns, the first calibration pattern having differently delayed rising edge transitions with respect to a timing reference and the second calibration pattern having differently delayed falling edge transitions with respect to the timing reference; and
a circuit to generate a timing offset for transmitting data to a second integrated circuit device, wherein the timing offset is derived from information received from the second integrated circuit device sampling the first calibration pattern and the second calibration pattern.

10. The integrated circuit device of claim 9, wherein the information includes rising edge samples of the differently delayed rising edge transitions and falling edge samples of the differently delayed falling edge transitions, the integrated circuit device further comprising:
a first circuit to determine a first timing location with respect to the timing reference based at least on the rising edge samples and to determine a second timing location with respect to the timing reference based at least on the falling edge samples;
the first circuit to compute a third timing location by averaging the first timing location and the second timing location; and
the first circuit to generate the timing offset by adding a predetermined phase shift to the third timing location.

11. The integrated circuit device of claim 10, wherein the first circuit further determines the first timing location by locating a first median location within the differently delayed rising edge transitions, and determines the second timing location by locating a second median location within the differently delayed falling edge transitions.

12. The integrated circuit device of claim 10, wherein the predetermined phase shift is a substantially 90° phase shift.

13. The integrated circuit device of claim 9,
wherein the interface transmits the data delayed by the timing offset to the second integrated circuit device; and
wherein the second integrated circuit device samples the data delayed by the timing offset using a clock signal, such that the timing offset delays the data to be substantially center aligned with edge transitions in the clock signal.

14. The integrated circuit device of claim 9, wherein the second calibration pattern is a phase-inverted version of the first calibration pattern.

15. The integrated circuit device of claim 9, wherein the first calibration pattern and the second calibration pattern are the same calibration pattern.

16. The integrated circuit device of claim 9, wherein the integrated circuit device is a memory controller device and the second integrated circuit device is a memory device.

17. A method of operation of an integrated circuit device, the method comprising:
sampling a first calibration pattern, having rising edge transitions, in response to differently delayed versions of a timing reference;
sampling a second calibration pattern, having falling edge transitions, in response to differently delayed versions of the timing reference; and
generating a timing offset for sampling data, wherein the timing offset is obtained based at least on information derived from sampling the first calibration pattern and the second calibration pattern.

18. The method of claim 17, wherein generating the timing offset comprises:
determining a first timing location within the rising edge transitions of the first calibration pattern based at least on the information;
determining a second timing location within the falling edge transitions of the second calibration pattern based at least on the information;
computing a third timing location by averaging the first timing location and the second timing location; and
generating the timing offset by adding a predetermined phase shift to the third timing location.

19. The method of claim 18,
wherein determining the first timing location comprises locating a first median location within the rising edge transitions; and
wherein determining the second timing location comprises locating a second median location within the falling edge transitions.

20. The method of claim 18, wherein the predetermined phase shift is a substantially 90° phase shift.

21. The method of claim 17, wherein the method further comprises sampling the data using a clock signal derived from a timing reference and the timing offset, such that the timing offset aligns a transition in the clock signal to be substantially in a center of a data bit in the data.

22. The method of claim 17, wherein the second calibration pattern is a phase-inverted version of the first calibration pattern.

23. The method of claim 17, wherein the first calibration pattern and the second calibration pattern are the same calibration pattern.

24. The method of claim 17, wherein the integrated circuit device is a memory controller device.

25. An integrated circuit device, comprising:
an interface to sample:
a first calibration pattern in response to differently delayed versions of a timing reference; and
a second calibration pattern in response to differently delayed versions of the timing reference; and
a circuit to generate a timing offset for sampling data, wherein the timing offset is obtained based at least on information derived from sampling the first calibration pattern and the second calibration pattern.

26. The integrated circuit device of claim 25, wherein the circuit:
determines a first timing location within the rising edge transitions of the first calibration pattern based at least on the information;
determines a second timing location within the falling edge transitions of the second calibration pattern based at least on the information;
computes a third timing location by averaging the first timing location and the second timing location; and
generates the timing offset by adding a predetermined phase shift to the third timing location.

27. The integrated circuit device of claim 26, wherein the circuit determines the first timing location by locating a first median location within the rising edge transitions, and determines the second timing location by locating a second median location within the falling edge transitions.

28. The integrated circuit device of claim 26, wherein the predetermined phase shift is a substantially 90° phase shift.

29. The integrated circuit device of claim 25, wherein the second calibration pattern is a phase-inverted version of the first calibration pattern.

30. The integrated circuit device of claim 25, wherein the first calibration pattern and the second calibration pattern are the same calibration pattern.

31. The integrated circuit device of claim 25, wherein the integrated circuit device is a memory controller device.
